(19) United States
(12) Patent Application Publication
(10) Pub. No.: US 2025/0148993 A1
(43) Pub. Date: May 8, 2025

(54) DISPLAY APPARATUS

(71) Applicant: SAMSUNG DISPLAY CO., LTD., YONGIN-SI (KR)

(72) Inventor: KEUNWOO KIM, YONGIN-SI (KR)

(21) Appl. No.: 18/937,249

(22) Filed: Nov. 5, 2024

(30) Foreign Application Priority Data
Nov. 7, 2023 (KR) 10-2023-0153093

(51) Int. Cl. G09G 3/3266; G09G 3/3258; H10K 59/121; H10K 59/131; H10K 59/35

(52) U.S. Cl. CPC G09G 3/3266; G09G 3/3258; H10K 59/1213; H10K 59/131; G09G 2300/0819; G09G 2300/0852; G09G 2310/0286; G09G 2310/06; H10K 59/35

(57) ABSTRACT

A display apparatus includes a plurality of pixels. Each pixel includes a light-emitting device, a first transistor configured to control a current supplied to the light-emitting device, a second transistor connected to a data line, a third transistor connected between a second terminal of the first transistor and a gate of the first transistor, a fourth transistor connected between a first terminal of the first transistor and a driving voltage line, and a fifth transistor connected between the second terminal of the first transistor and the light-emitting device. A first gate of the fourth transistor and a gate of the fifth transistor are connected to a first gate line that supplies a first gate signal, and a gate of the third transistor and a second gate of the fourth transistor are connected to a second gate line that supplies a second gate signal.

### CROSS-REFERENCE TO RELATED APPLICATION

This application claims priority under 35 U.S.C. § 119 to Korean Patent Application No. 10-2023-0153093, filed on Nov. 7, 2023 in the Korean Intellectual Property Office, the disclosure of which is incorporated by reference herein in its entirety.

### TECHNICAL FIELD

Embodiments of the present disclosure relate to a display apparatus.

### DISCUSSION OF RELATED ART

Display apparatuses are used for various purposes. As thicknesses and weights of display apparatuses have decreased, the range of applications of display apparatuses has also increased.

As display apparatuses are used in various ways, there may be various methods for designing display apparatuses of various shapes, and functions linked to or associated with display apparatuses have increased.

### SUMMARY

Embodiments of the present application include a display apparatus that may reduce costs by reducing the area of a bezel area by reducing the number of gate drivers.

Embodiments of the present application include a display apparatus that may reduce power consumption by reducing the number of data drivers.

According to an embodiment, a display apparatus includes a plurality of pixels. Each of the plurality of pixels includes a light-emitting device, a first transistor configured to control current supplied to the light-emitting device, a second transistor connected to a data line, a third transistor connected between a second terminal of the first transistor and a gate of the first transistor, a fourth transistor connected between a first terminal of the first transistor and a driving voltage line, and a fifth transistor connected between the second terminal of the first transistor and the light-emitting device. A first gate of the fourth transistor and a gate of the fifth transistor are connected to a first gate line that supplies a first gate signal, and a gate of the third transistor and a second gate of the fourth transistor are connected to a second gate line that supplies a second gate signal.

In an embodiment, each of the plurality of pixels further includes a first capacitor connected between the gate of the first transistor and the second transistor, a second capacitor connected between the second transistor and the driving voltage line, a sixth transistor connected between the gate of the first transistor and a first voltage line, a seventh transistor connected between the light-emitting device and a second voltage line, an eighth transistor connected between the second transistor and a third voltage line, and a ninth transistor configured to supply a bias voltage to the first terminal of the first transistor.

In an embodiment, the display apparatus further includes a data driving circuit configured to supply a plurality of data signals to the plurality of pixels. The data driving circuit includes a demultiplexer configured to alternately supply a data signal to a first data line based on a first control signal and supply the data signal to a second data line based on a second control signal.

In an embodiment, the demultiplexer includes a first switch transistor connected to the first data line and a second switch transistor connected to the second data line. The first control signal is supplied to a gate of the first switch transistor, and then the second control signal is supplied to a gate of the second switch transistor.

In an embodiment, each of the plurality of pixels is any one of a first pixel that emits a red light, a second pixel that emits a green light, and a third pixel that emits a blue light. The first pixel and the third pixel are connected to the first data line, and the second pixel is connected to the second data line.

In an embodiment, the data driving circuit further includes a data driver configured to output the plurality of data signals, and a data distributor configured to alternately supply the plurality of data signals to the first data line and the second data line respectively based on the first control signal and the second control signal.

In an embodiment, a gate of the eighth transistor is connected to the second gate line, a gate of the second transistor is connected to a third gate line that supplies a third gate signal, a gate of the sixth transistor is connected to a fourth gate line that supplies a fourth gate signal, and a gate of the seventh transistor and a gate of the ninth transistor are connected to a fifth gate line that supplies a fifth gate signal.

In an embodiment, the display apparatus further includes a gate driving circuit configured to supply a plurality of gate signals to the plurality of pixels. Each of the plurality of pixels operates in a non-emission period and an emission period during a frame period. The gate driving circuit is further configured to supply a first gate signal of a gate-off voltage to the first gate line in the non-emission period, supply a fourth gate signal of a gate-on voltage to the fourth gate line, in a first interval during the non-emission period, and supply a second gate signal of a gate-on voltage to the second gate line, in a second interval after the first interval during the non-emission period.

In an embodiment, the gate driving circuit is further configured to supply a third gate signal of a gate-on voltage to the third gate line, in a write interval after the second interval during the non-emission period.

In an embodiment, the gate driving circuit is further configured to supply a fifth gate signal of a gate-on voltage to the fifth gate line, in a third interval between the emission period and the write interval of the non-emission period.

In an embodiment, the gate driving circuit is further configured to supply a first gate signal of a gate-on voltage to the first gate line, in the emission period.

In an embodiment, a first on-time during which the gate driving circuit supplies a gate-on voltage in the first interval and the second interval is longer than a second on-time during which the gate driving circuit supplies a gate-on voltage in the write interval and the third interval.

According to an embodiment, a display apparatus includes a plurality of pixels. Each of the plurality of pixels includes a light-emitting device, a first transistor configured to control a current supplied to the light-emitting device, a second transistor connected to a data line, a third transistor connected between a second terminal of the first transistor and a gate of the first transistor, a fourth transistor connected between a first terminal of the first transistor and a driving voltage line, and a fifth transistor connected between the second terminal of the first transistor and the light-emitting device. A first gate signal is supplied to a gate of the third transistor and a first gate of the fourth transistor, and a second gate signal is supplied to a second gate of the fourth transistor and a gate of the fifth transistor.

In an embodiment, each of the plurality of pixels further includes a first capacitor connected between the gate of the first transistor and the second transistor, a second capacitor connected between the second transistor and the driving voltage line, a sixth transistor connected between the gate of the first transistor and a first voltage line, a seventh transistor connected between the light-emitting device and a second voltage line, an eighth transistor connected between the second transistor and a third voltage line, and a ninth transistor configured to supply a bias voltage to the first terminal of the first transistor.

In an embodiment, a data signal is alternately supplied to a first data line based on a first control signal and supplied to a second data line based on a second control signal.

In an embodiment, each of the plurality of pixels is any one of a first pixel that emits a red light, a second pixel that emits a green light, and a third pixel that emits a blue light. The first pixel and the third pixel are connected to the first data line, and the second pixel is connected to the second data line.

In an embodiment, the first gate signal is supplied to a gate of the eighth transistor, a third gate signal is supplied to a gate of the second transistor, a fourth gate signal is supplied to a gate of the sixth transistor, and a fifth gate signal is supplied to a gate of the seventh transistor and a gate of the ninth transistor.

In an embodiment, the pixel operates in a non-emission period and an emission period during a frame period. The non-emission period includes a first interval during which the sixth transistor is turned on to apply a first voltage from the first voltage line to the gate of the first transistor, and a second interval during which the third transistor and the fourth transistor are turned on to store a threshold voltage of the first transistor in the first capacitor, and the eighth transistor is turned on to apply a third voltage from the third voltage line to a node where the first capacitor is connected to the second capacitor.

In an embodiment, the non-emission period further includes, after the second interval, a write interval during which the second transistor is turned on to apply a data signal from the data line to the gate of the first transistor.

In an embodiment, the non-emission period further includes, after the write interval, a third interval during which the seventh transistor is turned on to supply a second voltage from the second voltage line to the light-emitting device, and the ninth transistor is turned on to supply the bias voltage to the first terminal of the first transistor.

In an embodiment, there may be further provided a computer program stored in a computer-readable recording medium for execution for implementing embodiments of the present disclosure.

In an embodiment, there may be further provided a computer-readable medium having recorded thereon a computer program for executing a method for implementing embodiments of the present disclosure.

### BRIEF DESCRIPTION OF THE DRAWINGS

The above and other aspects and features of the present disclosure will become more apparent by describing in detail embodiments thereof with reference to the accompanying drawings, in which:

FIGS. 1A and 1B are plan views schematically illustrating a display apparatus, according to an embodiment;

FIG. 2 is a diagram schematically illustrating a display apparatus, according to an embodiment;

FIG. 3 is a diagram schematically illustrating a display apparatus, according to an embodiment;

FIGS. 4A and 4B are equivalent circuit diagrams illustrating a pixel of FIG. 3, according to an embodiment;

FIG. 5 is a diagram illustrating signals supplied to the pixel PX of FIG. 3;

FIGS. 6A and 6B are diagrams for describing a demultiplexer, according to an embodiment;

FIG. 7 is a timing diagram for describing a switching operation of the demultiplexer of FIGS. 6A and 6B;

FIGS. 8A, 8B, and 8C are diagrams for describing a structure and an operation of a transistor including multiple gates; and

FIG. 9 is a diagram illustrating an experimental result for describing effects of embodiments of the present disclosure.

### DETAILED DESCRIPTION

Embodiments of the present disclosure will be described more fully hereinafter with reference to the accompanying drawings. Like reference numerals may refer to like elements throughout the accompanying drawings.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

It will be understood that the terms “first,” “second,” “third,” etc. are used herein to distinguish one element from another, and the elements are not limited by these terms. Thus, a “first” element in an embodiment may be described as a “second” element in another embodiment.

As used herein, the singular forms “a,” “an,” and “the” are intended to include the plural forms as well, unless the context clearly indicates otherwise.

It will be understood that the terms “including,” and “having,” are intended to indicate the existence of the features or elements described in the specification, and are not intended to preclude the possibility that one or more other features or elements may exist or may be added.

“A and/or B” as used herein indicates selecting only A, selecting only B, or selecting both A and B. Also, “at least one of A and B” as used herein indicates selecting only A, selecting only B, or selecting both A and B.

In the following embodiments, when X and Y are connected to each other, it may include a case where X and Y are electrically connected to each other, a case where X and Y are functionally connected to each other, and a case where X and Y are directly connected to each other. Here, X and Y may be objects (e.g., devices, elements, circuits, wirings, electrodes, terminals, conductive films, and layers). Accordingly, a connection relationship is not limited to a certain connection relationship, for example, a connection relationship shown in the drawings or the detailed description, and may include other connection relationships other than the connection relationship shown in the drawings or the detailed description.

For example, when X and Y are electrically connected, one or more elements (e.g., switches, transistors, capacitors, inductors, resistors, or diodes) that enable electrical connection between X and Y may be connected between X and Y.

In the following embodiments, the term “on” used in association with a device state may refer to a state in which a device is activated, and the term “off” may refer to a state in which a device is deactivated. The term “on” used in association with a signal received by a device may refer to a signal for activating a device, and the term “off” may refer to a signal for deactivating a device. A device may be activated by a high-level voltage or a low-level voltage. For example, a P-channel transistor (P-type transistor) is activated by a low-level voltage, and an N-channel transistor (N-type transistor) is activated by a high-level voltage. Accordingly, it should be understood that “on” voltages for the P-type transistor and the N-type transistor have opposite (high and low) voltage levels.

In the following embodiments, an x-direction, a y-direction, and a z-direction are not limited to directions along three axes of the rectangular coordinate system, and may be interpreted in a broader sense. For example, the x-direction, the y-direction, and the z-direction may be perpendicular to one another, or may represent different directions that are not perpendicular to one another.

It should be understood that descriptions of features or aspects within each embodiment should typically be considered as available for other similar features or aspects in other embodiments, unless the context clearly indicates otherwise.

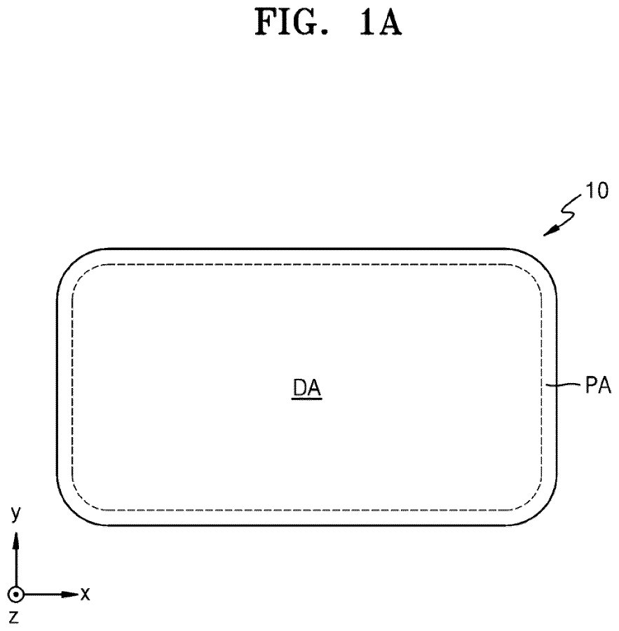

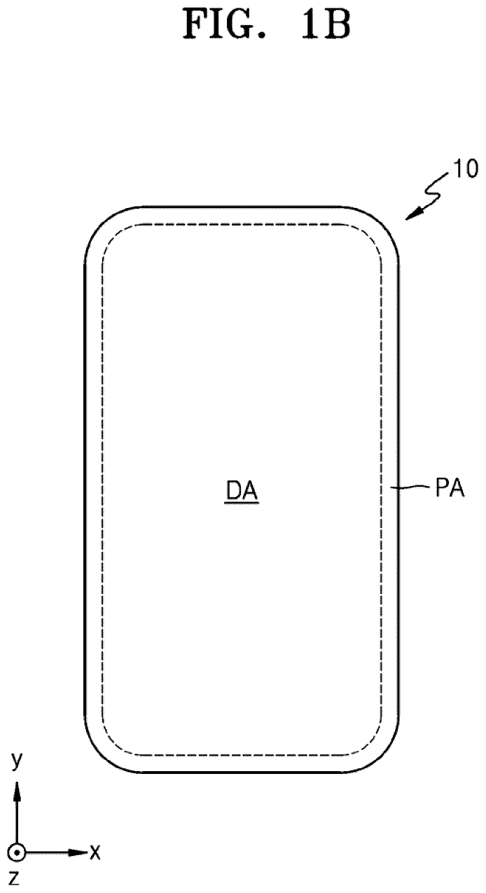

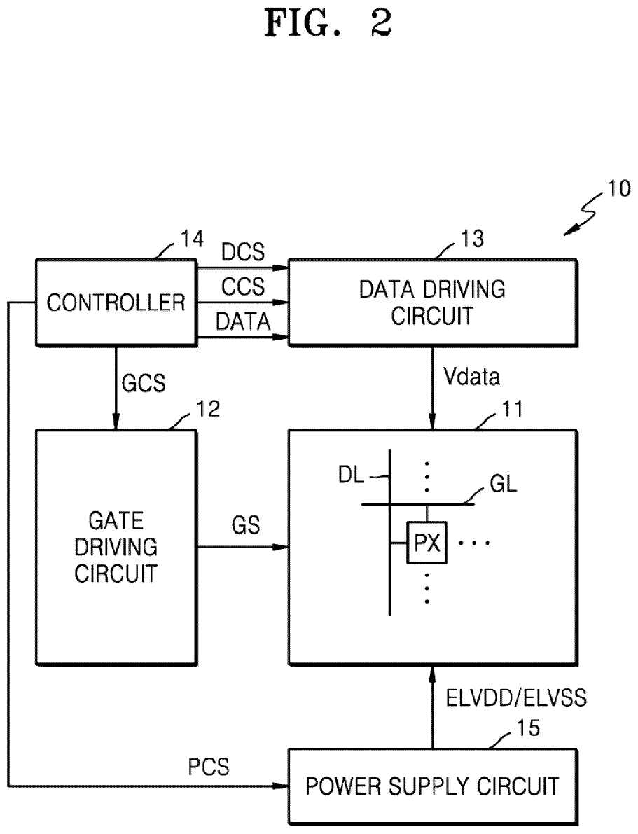

FIGS. 1A and 1B are plan views schematically illustrating a display apparatus, according to an embodiment. FIG. 2 is a diagram schematically illustrating a display apparatus, according to an embodiment.

Referring to FIGS. 1A and 1B, a display apparatus 10 may include a display area DA in which an image is displayed, and a peripheral area PA disposed outside of the display area DA. The display area DA may be entirely surrounded by the peripheral area PA.

In an embodiment, the display area DA may have a rectangular shape in a plan view. In an embodiment, the display area DA may have a polygonal shape (e.g., a triangular shape, a pentagonal shape, or a hexagonal shape), a circular shape, an elliptical shape, or an irregular shape in a plan view. The display area DA may have a shape with round corners. In an embodiment, the display apparatus 10 may include the display area DA having a shape in which a length in an x-direction is greater than a length in a y-direction, as shown in FIG. 1A. In an embodiment, the display apparatus 10 may include the display area DA having a shape in which a length in the y-direction is greater than a length in the x-direction, as shown in FIG. 1B.

Referring to FIG. 2, the display apparatus 10 according to an embodiment may include a pixel unit 11 (also referred to as a display panel), a gate driving circuit 12, a data driving circuit 13, a controller 14, and a power supply circuit 15.

The pixel unit 11 may be disposed in the display area DA. Various conductive lines for transmitting an electrical signal to be applied to the display area DA, outer circuits electrically connected to pixel circuits, and pads to which a printed circuit board or a driver integrated circuit (IC) chip is attached may be disposed in the peripheral area PA. For example, the gate driving circuit 12, the data driving circuit 13, the controller 14, and the power supply circuit 15 may be disposed in the peripheral area PA. The peripheral area PA may be a bezel area.

As shown in FIG. 2, a plurality of gate lines GL, a plurality of data lines DL, and a plurality of pixels PX connected to the gate lines GL and the data lines DL may be disposed in the display area DA. The plurality of pixels PX may be disposed in any of various arrangements such as, for example, a stripe arrangement, a pentile arrangement (diamond arrangement), or a mosaic arrangement, and may display an image. Each pixel PX may include an organic light-emitting diode OLED as a display element (light-emitting device), and the organic light-emitting diode OLED may be connected to a pixel circuit. The pixel circuit may include a plurality of transistors and at least one capacitor. Each pixel PX may emit light, for example, red light, green light, blue light, or white light, through the organic light-emitting diode OLED. Each pixel PX may be connected to at least one corresponding gate line from among the plurality of gate lines GL and a corresponding data line from among the plurality of data lines DL.

Each of the gate lines GL may extend in the x-direction (row direction) and may be connected to the pixels PX disposed in the same row. The gate line GL may transmit a gate signal to the pixels PX in the same row. Each of the data lines DL may extend in the y-direction (column direction) and may be connected to the pixels PX disposed in the same column. The data line DL may transmit a data signal to each of the pixels PX in the same column in synchronization with a gate signal.

In an embodiment, the peripheral area PA may be a non-display area in which the pixels PX are not disposed. In an embodiment, a plurality of pixels PX may be disposed in a part of the peripheral area PA. For example, a plurality of pixels PX may overlap the gate driving circuit 12 at at least one corner of the peripheral area PA. Accordingly, the bezel area may be reduced and the display area DA may be expanded.

The gate driving circuit 12 may be connected to the plurality of gate lines GL, may generate a gate signal in response to a control signal GCS received from the controller 14, and may sequentially supply the gate signal to the gate lines GL. The gate line GL may be connected to a gate of a transistor included in the pixel PX. A gate signal may be a gate control signal that controls turn-on or turn-off of a transistor having a gate connected to the gate line GL. The gate signal may be a signal including a gate-on voltage that turns on the transistor and a gate-off voltage that turns off the transistor.

Although the pixel PX is connected to one gate line GL in FIG. 2, this is merely an example. In an embodiment, the pixel PX may be connected to two or more gate lines, and the gate driving circuit 12 may supply two or more gate signals having different timings at which a gate-on voltage is applied to the corresponding gate lines.

The data driving circuit 13 may convert input image data DATA having a gray level input from the controller 14 into a data signal Vdata in the form of a voltage. The data driving circuit 13 may convert the input image data DATA having a gray level input from the controller 14 into a data signal in the form of current.

Output lines through which the data signal Vdata is output from the data driving circuit 13 may be connected to the plurality of data lines DL. The data driving circuit 13 may supply the data signal Vdata to a plurality of output lines in response to a control signal DCS from the controller 14, and may selectively connect the plurality of output lines to corresponding data lines DL in response to a distribution control signal CCS received from the controller 14. The data signal Vdata supplied to the data line DL may be supplied to the pixel PX to which a gate signal GS is supplied.

The controller 14 may generate control signals GCS, DCS, CCS, and PCS based on signals input from outside of the controller 14, and may supply the control signals GCS, DCS, CCS, and PCS to the gate driving circuit 12, the data driving circuit 13, and the power supply circuit 15. The control signal GCS output to the gate driving circuit 12 may include a plurality of clock signals and a gate start signal. The control signal DCS output to the data driving circuit 13 may include a data start signal and clock signals.

The power supply circuit 15 may generate voltages utilized to drive the pixel PX in response to a control signal PCS from the controller 14. The power supply circuit 15 may generate a first driving voltage ELVDD and a second driving voltage ELVSS, and may supply the first driving voltage ELVDD and the second driving voltage ELVSS to the pixels PX. The first driving voltage ELVDD may be a high-level voltage provided to one terminal of a driving transistor connected to a first electrode (pixel electrode or anode) of a display element included in the pixel PX. The second driving voltage ELVSS may be a low-level voltage provided to a second electrode (counter electrode or cathode) of the display element included in the pixel PX.

The display apparatus 10 may include a display panel, and the display panel may include a substrate. The pixels PX may be disposed in the display area DA of the substrate. A part of or the entirety of the gate driving circuit 12 may be directly formed in the peripheral area PA of the substrate during a process of forming a transistor constituting a pixel circuit in the display area DA of the substrate. The data driving circuit 13, the controller 14, and the power supply circuit 15 may each be formed as a separate integrated circuit chip or one integrated circuit chip, and may be disposed on a flexible printed circuit board (FPCB) electrically connected to a pad disposed on a side of the substrate. In an embodiment, the data driving circuit 13, the controller 14, and the power supply circuit 15 may be directly disposed on the substrate by using, for example, a chip-on-glass (COG) or chip-on-plastic (COP) method.

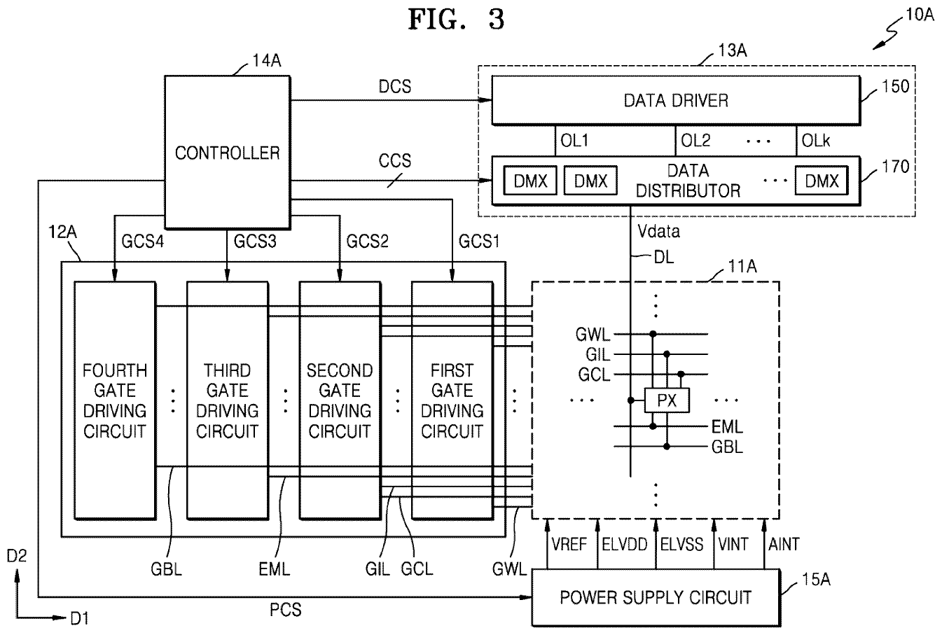

FIG. 3 is a diagram schematically illustrating a display apparatus, according to an embodiment.

Referring to FIG. 3, a display apparatus 10A may include a pixel unit 11A (also referred to as a display panel), a gate driving circuit 12A, a data driving circuit 13A, a controller 14A, and a power supply circuit 15A. The display apparatus 10A may be an embodiment of the display apparatus 10 of FIG. 2. Hereinafter, for convenience of explanation, the same elements as those of the display apparatus 10 of FIG. 2 will not be described in detail.

The pixel unit 11A may include a plurality of pixels PX. Each pixel PX may be connected to a first gate line GWL that transmits a gate signal GW, a second gate line GIL that transmits a second gate signal GI, a third gate line GCL that transmits a third gate signal GC, a fourth gate line EML that transmits a fourth gate signal EM, a fifth gate line GBL that transmits a fifth gate signal GB, and a data line DL that transmits a data signal Vdata. Because light emission of the pixel PX is controlled by the fourth gate signal EM, the fourth gate signal EM may be referred to as an emission control signal and the fourth gate line EML may be referred to as an emission control line.

The pixel PX may receive a first driving voltage ELVDD (or a first voltage), a second driving voltage ELVSS (or a second voltage), a reference voltage VREF (or a third voltage), a first initialization voltage VINT (or a fourth voltage), and a second initialization voltage AINT (or a fifth voltage).

The gate driving circuit 12A may be connected to the first to fifth gate lines GWL, GIL, GCL, EML, and GBL, and may sequentially supply the first to fifth gate signals GW, GI, GC, EM, and GB to the first to fifth gate lines GWL, GIL, GCL, EML, and GBL. The gate driving circuit 12A may include first to fourth gate driving circuits. Each of the first to fourth gate driving circuits may include a plurality of stages.

The first gate driving circuit may be connected to a plurality of first gate lines GWL and may sequentially supply the first gate signal GW to the first gate lines GWL. The second gate driving circuit may be connected to a plurality of second gate lines GIL and a plurality of third gate lines GCL, may sequentially supply the second gate signal GI to the second gate lines GIL, and may sequentially supply the third gate signal GC to the third gate lines GCL. The third gate driving circuit may be connected to a plurality of fourth gate lines EML, and may sequentially supply the fourth gate signal EM to the fourth gate lines EML. The fourth gate driving circuit may be connected to a plurality of fifth gate lines GBL, and may sequentially supply the fifth gate signal GB to the fifth gate lines GBL.

In an embodiment, the first to fifth gate signals GW, GI, GC, EM, and GB may be supplied to the first to fifth gate lines GWL, GIL, GCL, EML, and GBL of each pixel row at certain timings. In an embodiment, the first gate signal GW may be sequentially supplied to the first gate line GWL of each pixel row at a certain timing, and the second to fifth gate signals GI, GC, EM, and GB may be simultaneously supplied to the second to fifth gate lines GIL, GCL, EML, and GBL of two pixel rows, and may be sequentially supplied in units of two pixel rows. For example, the third gate driving circuit may simultaneously supply the fourth gate signal EM to the fourth gate lines EML of two pixel rows, and may sequentially supply the fourth gate signal EM to the fourth gate lines EML in units of two pixel rows.

The data driving circuit 13A may include a data driver 150 (also referred to as a data driver circuit) and a data distributor 170 (also referred to as a data distributor circuit). The data driver 150 may be connected to a plurality of output lines OL1 to OLk, where k is a positive integer greater than or equal to 2, and the plurality of output lines OL1 to OLk may be connected to a plurality of data lines through the data distributor 170. The data driver 150 may supply the data signal Vdata to the data distributor 170 through the output lines OL1 to OLk.

The data distributor 170 may be connected between the plurality of output lines OL1 to OLk and the plurality of data lines. The data distributor 170 may include k demultiplexers DMX including a plurality of switches. That is, the data distributor 170 may include the same number of demultiplexers DMX as the number of output lines. One end of the demultiplexer DMX may be connected to one corresponding output line from among the plurality of output lines OL1 to OLk. The other end of the demultiplexer DMX may be connected to m data lines, where m is a positive integer. The demultiplexer DMX may supply the data signal Vdata supplied from a corresponding output line to m data lines. The data distributor 170 may include k demultiplexers DMX, and each of the demultiplexers DMX may be connected to m data lines. In this case, the total number of data lines included in the data driving circuit 13A may be (k×m). Because fewer output lines are utilized than data lines by using the demultiplexer DMX, the number of output lines connected to the data driver 150 may be reduced, which may thereby reduce manufacturing costs. Also, because the number of data driving circuits 13A that drive at a frequency utilized by the display apparatus 10 may be reduced by using the demultiplexer DMX, power consumption may be reduced. The demultiplexer DMX may include a plurality of switches (m switches) connected to a corresponding output line and m data lines.

The power supply circuit 15A may supply the first driving voltage ELVDD and the second driving voltage ELVSS to the pixels PX of the pixel unit 11A. The power supply circuit 15A may generate the reference voltage VREF, the first initialization voltage VINT, and the second initialization voltage AINT, and may supply the reference voltage VREF, the first initialization voltage VINT, and the second initialization voltage AINT to the pixels PX of the pixel unit 11A.

The controller 14A may generate control signals GCS1 to GCS4, CCS, DCS, and PCS based on signals input from outside of the controller 14A, and may supply the control signals GCS1 to GCS4, CCS, DCS, and PCS to the gate driving circuit 12A, the data driving circuit 13A, and the power supply circuit 15A. The controller 14A may supply a corresponding control signal from among the control signals CGS1 to GCS4 to each of the first to fourth gate driving circuits of the gate driving circuit 12A. The controller 14A may output the distribution control signal CCS to the data distributor 170, and the data distributor 170 may selectively connect the output lines OL1 to OLk to the data lines in response to the distribution control signal CCS. The controller 14A may output m distribution control signals CCS to the demultiplexers DMX so that m data signals supplied through one output line are time divided and supplied to m data lines. The m distribution control signals CCS may be sequentially output so as not to overlap each other.

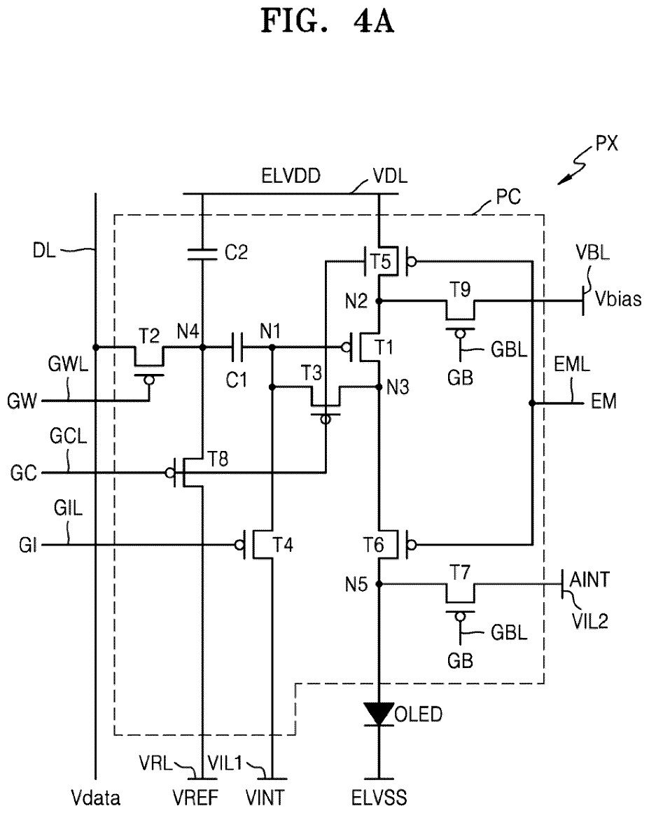

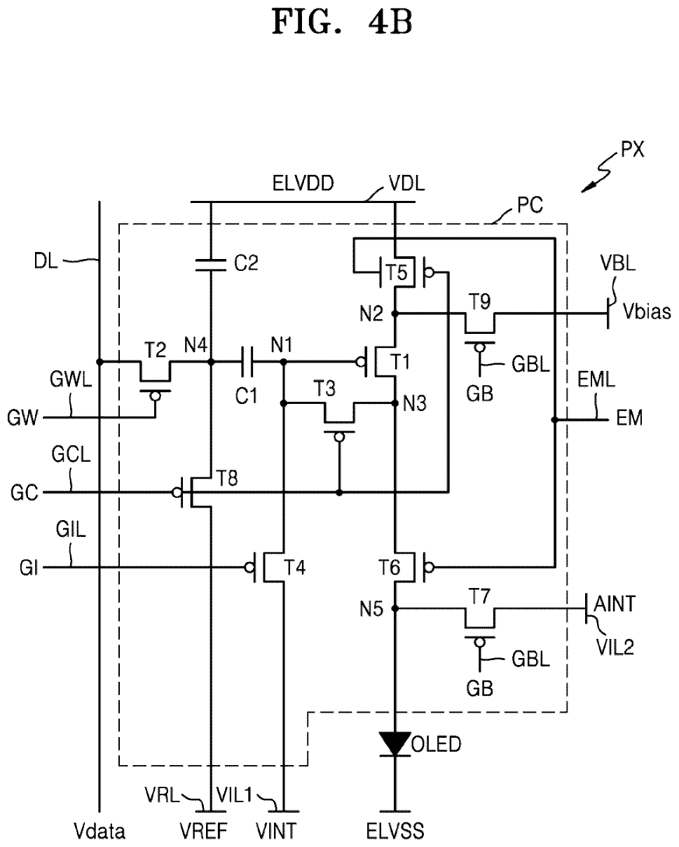

FIGS. 4A and 4B are equivalent circuit diagrams illustrating a pixel of FIG. 3, according to an embodiment.

Referring to FIG. 4A, the pixel PX may include a pixel circuit PC and an organic light-emitting diode OLED as a display element connected to the pixel circuit PC.

The pixel circuit PC of the pixel PX may include first to ninth transistors T1 to T9, a first capacitor C1, a second capacitor C2, and signal lines connected to the first to ninth transistors T1 to T9, the first capacitor C1, and the second capacitor C2. The signal lines may include a data line DL, a first gate line GW, a second gate line GIL, a third gate line GCL, a fourth gate line EML, a fifth gate line GBL, a driving voltage line VDL, a reference voltage line VRL, a first initialization voltage line VIL1, and a second initialization voltage line VIL2.

The first transistor T1 may be a driving transistor in which a magnitude of source-drain current is determined according to a gate-source voltage Vgs, and the second to ninth transistors T2 to T9 may be switching transistors that are turned on/off according to a gate-source voltage, substantially, a gate voltage. The first to ninth transistors T1 to T9 may be implemented as thin-film transistors. According to a type (p-type or n-type) and/or an operating condition of a transistor, a first terminal of each of the first to ninth transistors T1 to T9 may be a source or a drain and a second terminal may be a terminal different from the first terminal. For example, when a first terminal is a source, a second terminal may be a drain.

The first to ninth transistors T1 to T9 may be P-type silicon thin-film transistors. A gate-on voltage of a gate signal that turns on the first to ninth transistors T1 to T9 may be a low-level voltage (second-level voltage), and a gate-off voltage of a gate signal that turns off the first to ninth transistors T1 to T9 may be a high-level voltage (first-level voltage).

The first transistor T1 may be connected between the driving voltage line VDL and the organic light-emitting diode OLED. The first transistor T1 may be connected to the driving voltage line VDL via the fifth transistor T5, and may be electrically connected to the organic light-emitting diode OLED via the sixth transistor T6. The first transistor T1 includes a gate connected to a first node N1, a first terminal connected to a second node N2, and a second terminal connected to a third node N3. The first transistor T1 may supply a driving current corresponding to a voltage applied to the first node N1 to the organic light-emitting diode OLED according to a switching operation of the second transistor T2.

The second transistor T2 may be connected to the data line DL and a fourth node N4. The second transistor T2 may include the gate connected to the first gate line GWL, a first terminal connected to the data line DL, and a second terminal connected to the fourth node N4. The second transistor T2 may be turned on according to a first gate signal GW received through the first gate line GWL to transmit data signal Vdata transmitted through the data line DL to the fourth node N4.

The third transistor T3 may be connected between the first node N1 and the third node N3. The third transistor T3 may be connected to the organic light-emitting diode OLED via the sixth transistor T6. The third transistor T3 may include a gate connected to the third gate line GCL, a first terminal connected to the third node N3, and a second terminal connected to the first node N1. The third transistor T3 may be turned on according to a third gate signal GC received through the third gate line GCL to diode-connect the first transistor T1. When the first transistor T1 is diode-connected, a threshold voltage of the first transistor T1 may be compensated.

The fourth transistor T4 may be connected between the first node N1 and the first initialization voltage line VIL1. The fourth transistor T4 may include a gate connected to the second gate line GIL, a first terminal connected to the first node N1, and a second terminal connected to the first initialization voltage line VIL1. The fourth transistor T4 may be turned on according to the second gate signal GI received through the second gate line GIL to transmit a first initialization voltage VINT to the first node N1 and initialize the first node N1, that is, the gate of the first transistor T1.

The fifth transistor T5 may be connected between the driving voltage line VDL and the second node N2. The fifth transistor T5 may include a first gate and a second gate. The fifth transistor T5 may be a dual gate transistor including the first gate that is a top gate disposed over a semiconductor and the second gate that is a bottom gate disposed under the semiconductor. In an embodiment, referring to FIG. 4A, the fifth transistor T5 may include the first gate connected to the fourth gate line EML, the second gate connected to the third gate line GCL, a first terminal connected to the driving voltage line VDL, and a second terminal connected to the second node N2. In an embodiment, referring to FIG. 4B, the fifth transistor T5 may include the first gate connected to the third gate line GCL, the second gate connected to the fourth gate line EML, a first terminal connected to the driving voltage line VDL, and a second terminal connected to the second node N2.

The sixth transistor T6 may be connected to the third node N3 and the organic light-emitting diode OLED. The sixth transistor T6 may include a gate connected to the fourth gate line EML, a first terminal connected to the third node N3, and a second terminal connected to a pixel electrode of the organic light-emitting diode OLED.

When the first transistor T5 and the sixth transistor T6 are simultaneously turned on according to a fourth gate signal EM received through the fourth gate line EML, a driving current may flow through the organic light-emitting diode OLED.

The seventh transistor T7 may be connected between the organic light-emitting diode OLED and the second initialization voltage line VIL2. The seventh transistor T7 may include a gate connected to the fifth gate line GBL, a first terminal connected to a fifth node N5, that is, the second terminal of the sixth transistor T6 and the pixel electrode of the organic light-emitting diode OELD, and a second terminal connected to the second initialization voltage line VIL2. The seventh transistor T7 may be turned on according to a fifth gate signal GB received through the fifth gate line GBL to transmit a second initialization voltage AINT to the pixel electrode of the organic light-emitting diode OLED and initialize the pixel electrode of the organic light-emitting diode OLED.

The eighth transistor T8 may be connected between the fourth node N4 and the reference voltage line VRL. The eighth transistor T8 may include a gate connected to the third gate line GCL, a first terminal connected to the fourth node N4, and a second terminal connected to the reference voltage line VRL. The gate of the eighth transistor T8 may be connected to the gate of the third transistor T3. The eighth transistor T8 may be turned on according to the third gate signal GC received through the third gate line GCL to transmit a reference voltage VREF to the fourth node N4 and initialize the fourth node N4.

The ninth transistor T9 may be connected to the second node N2 and may supply a bias voltage Vbias to the first terminal of the first transistor T1. The ninth transistor T9 may include a gate connected to the fifth gate line GBL, a first terminal connected to the bias voltage line VBL supplying the bias voltage Vbias, and a second terminal connected to the first terminal of the first transistor T1. The ninth transistor T9 may be turned on according to the fifth gate signal GB received through the fifth gate line GBL to transmit the bias voltage Vbias to the first terminal of the first transistor T1 and compensate for a change in current characteristic of the first transistor T1 by controlling a gate-source voltage of the first transistor T1.

The first capacitor C1 may be connected between the first node N1 and the fourth node N4. The first capacitor C1 may store a voltage corresponding to a voltage difference between the first node N1 and the fourth node N4. The first capacitor C1 may be a storage capacitor. The first capacitor C1 may store the threshold voltage of the first transistor T1 and the data signal Vdata written through the second transistor T2.

The second capacitor C2 may be connected between the driving voltage line VDL and the fourth node N4. The second capacitor C2 may store a voltage corresponding to a voltage difference between the driving voltage line VDL and the fourth node N4. The second capacitor C2 may maintain the data signal Vdata written through the second transistor T2.

The organic light-emitting diode OLED may include the pixel electrode (e.g., an anode) and a counter electrode (e.g., a cathode) facing the pixel electrode, and the counter electrode may receive a second driving voltage ELVSS. The organic light-emitting diode OLED may display an image by receiving a driving current corresponding to the data signal Vdata from the first transistor T1 and emitting light in a certain color.

In an embodiment, a plurality of transistors included in the pixel circuit may be P-type transistors. In an embodiment, a plurality of transistors included in the pixel circuit may be N-type transistors, or some may be N-type transistors and others may be P-type transistors.

A transistor according to an embodiment may be any one of, for example, an amorphous silicon thin-film transistor (TFT), a low temperature polysilicon (LTPS) TFT, and an oxide TFT. The oxide TFT may include an oxide such as, for example, amorphous indium-gallium-zinc-oxide (IGZO), zinc-oxide (ZnO), or titanium oxide (TiO) as a semiconductor layer (active layer).

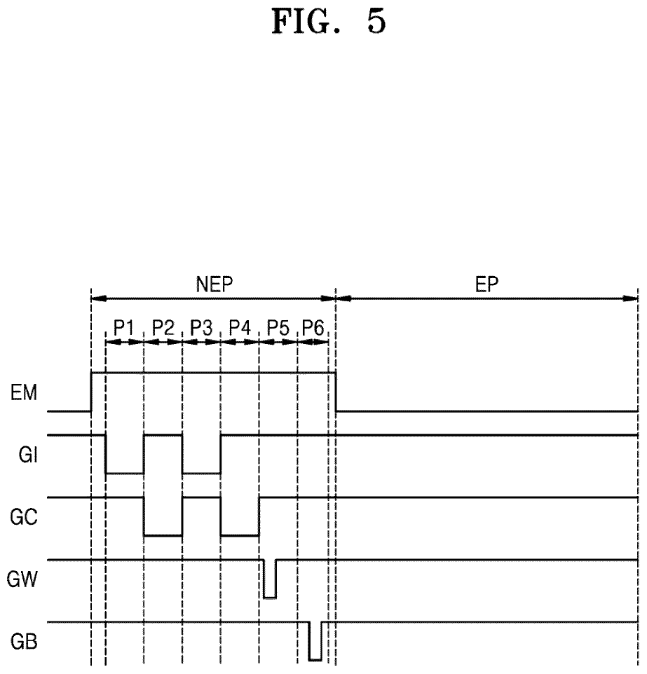

FIG. 5 is a diagram illustrating signals supplied to the pixel PX of FIG. 3.

During a non-emission period NEP, the gate driving circuit 12A may supply the first to fifth gate signals GW, GI, GC, EM, and GB to the first to fifth gate lines GWL GIL, GCL, EML, and GBL. A start timing and an end timing of a gate-on voltage maintenance period and a gate-off voltage maintenance period of the first to fifth gate signals GW, GI, GC, EM, and GB may be the same or different.

During the non-emission period NEP, the power supply circuit 15A may supply the first driving voltage ELVDD through the driving voltage line VDL, may supply the reference voltage VREF through the reference voltage line VRL, may supply the first initialization voltage VINT through the first initialization voltage line VIL1, and may supply the second initialization voltage line AINT through the second initialization voltage line VIL2.

Referring to FIG. 5, the non-emission period NEP may include a period during which a data signal corresponding to an image is written. A period during which the fourth gate signal is a gate-off voltage may be the non-emission period NEP, and a period during which the fourth gate signal EM is a gate-on voltage may be an emission period EP. The non-emission period NEP may include at least one initialization period and at least one compensation period. The non-emission period NEP may include first to sixth intervals P1 to P6.

The first interval P1 and the third interval P3 may be initialization periods during which the first node N1 to which a gate of the first transistor T1 is connected is initialized.

In the first interval P1 and the third interval P3, the second gate signal GI of a gate-on voltage (second-level voltage) may be supplied to the second gate line GIL. The first gate signal GW, the third gate signal GC, the fourth gate signal EM, and the fifth gate signal GB of a gate-off voltage (first-level voltage) may be respectively supplied to the first gate line GWL, the third gate line GCL, the fourth gate line EML, and the fifth gate line GBL. The fourth transistor T4 may be turned on by the second gate signal GI to initialize the gate of the first transistor T1 to the first initialization voltage VINT.

The second interval P2 and the fourth interval P4 may be compensation periods during which a threshold voltage of the first transistor T1 is compensated.

In the second interval P2 and the fourth interval P4, the third gate signal GC of a gate-on voltage may be supplied to the third gate line GCL. The first gate signal GW, the second gate signal GI, the fourth gate signal EM, and the fifth gate signal GB of a gate-off voltage may be respectively supplied to the first gate line GWL, the second gate line GIL, the fourth gate line EML, and the fifth gate line GBL. The third transistor T3, the fifth transistor T5, and the eighth transistor T8 may be turned on by the third gate signal GC.

The first driving voltage ELVDD may be supplied to the second node N2 by the fifth transistor T5 that is turned on, and the reference voltage VREF may be supplied to the fourth node N4 by the eighth transistor T8 that is turned on. A difference (ELVDD-Vth) between the first driving voltage ELVDD and the threshold voltage Vth of the first transistor T1 may be supplied to the gate of the first transistor T1 that is diode-connected by the third transistor T3 that is turned on. The first capacitor C1 may be charged with a voltage corresponding to the threshold voltage Vth of the first transistor T1. That is, the pixel PX may compensate for the threshold voltage of the first transistor T1 by the reference voltage VREF and the first driving voltage ELVDD that are constant voltages.

As initialization and threshold voltage compensation are alternately repeated during the first interval P1 to the fourth interval P4, an on-bias voltage may be applied to the first transistor T1 a certain number of times to shift the threshold voltage of the first transistor T1 in a certain direction and compensate for hysteresis. The on-bias voltage may be a voltage difference between the gate and a source (first terminal) of the first transistor T1 which turns on the first transistor T1. Initialization and threshold voltage compensation may be alternately repeated multiple times. An example where initialization and threshold voltage compensation are alternately repeated twice is illustrated in FIG. 5. In an embodiment, initialization and threshold voltage compensation may each be performed once.

The fifth interval P5 may be a write interval (data programming period) during which a data signal is applied to the pixel PX. In the fifth interval P5, a voltage corresponding to a data signal may be transmitted to a gate of a driving transistor (first transistor).

In the fifth interval P5, the first gate signal GW of a gate-on voltage may be supplied to the first gate line GWL. The second gate signal GI, the third gate signal GC, the fourth gate signal EM, and the fifth gate signal GB of a gate-off voltage may be respectively supplied to the second gate line GIL, the third gate line GCL, the fourth gate line EML, and the fifth gate line GBL.

The second transistor T2 may be turned on by the first gate signal GW. The second transistor T2 that is turned on may transmit the data signal Vdata supplied from the data line DL to the fourth node N4. Accordingly, a voltage of the fourth node N4 may change by a voltage corresponding to a difference between the reference voltage VREF and the data signal Vdata, and a voltage of the first node N1 may also change in response to a voltage change amount of the fourth node N4. Accordingly, the first capacitor C1 may be charged with a data voltage corresponding to the data signal Vdata and the threshold voltage Vth of the first transistor T1.

The sixth interval P6 may be a period during which the bias voltage Vbias is applied to the first transistor T1 and the second initialization voltage AINT is applied to the organic light-emitting diode OLED.

In the sixth interval P6, the fifth gate signal GB of a gate-on voltage may be supplied to the fifth gate line GBL. The first gate signal GW, the second gate signal GI, the third gate signal GC, and the fourth gate signal EM of a gate-off voltage may be respectively supplied to the first gate line GWL, the second gate line GIL, the third gate line GCL, and the fourth gate line EML.

A pixel electrode of the organic light-emitting diode OLED may be initialized to the second initialization voltage AINT by the seventh transistor T7 that is turned on. Accordingly, the sixth interval P6 may be a period during which the pixel electrode of the organic light-emitting diode OLED is initialized. The bias voltage of a constant voltage may be supplied to the second node N2 by the ninth transistor T9 that is turned on. Accordingly, the sixth interval P6 may be a biasing period during which the bias voltage Vbias is supplied to a first terminal of the first transistor T1.

In the emission period EP, the organic light-emitting diode OLED may emit light. In the emission period EP, the fourth gate signal EM of a gate-on voltage may be supplied to the fourth gate line EML. The first gate signal GW, the second gate signal GI, the third gate signal GC, and the fifth gate signal GB of a gate-off voltage may be respectively supplied to the first gate line GWL, the second gate line GIL, the third gate line GCL, and the fifth gate line GBL. The fifth transistor T5 and the sixth transistor T6 may be turned on by the fourth gate signal EM.

A current path may be formed from the driving voltage line VDL to the organic light-emitting diode OLED by the fifth transistor T5 and the sixth transistor T6 which are turned on. The first transistor T1 may output a driving current having a magnitude corresponding to a data voltage stored in the first capacitor C1, and the organic light-emitting diode OLED may emit light at a luminance corresponding to the magnitude of the driving current, irrespective of the threshold voltage Vth of the first transistor T1.

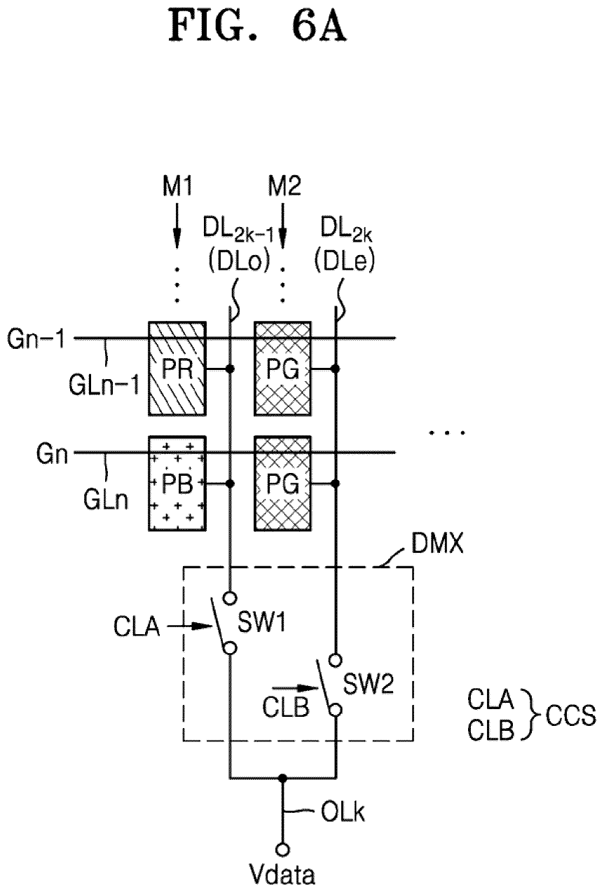

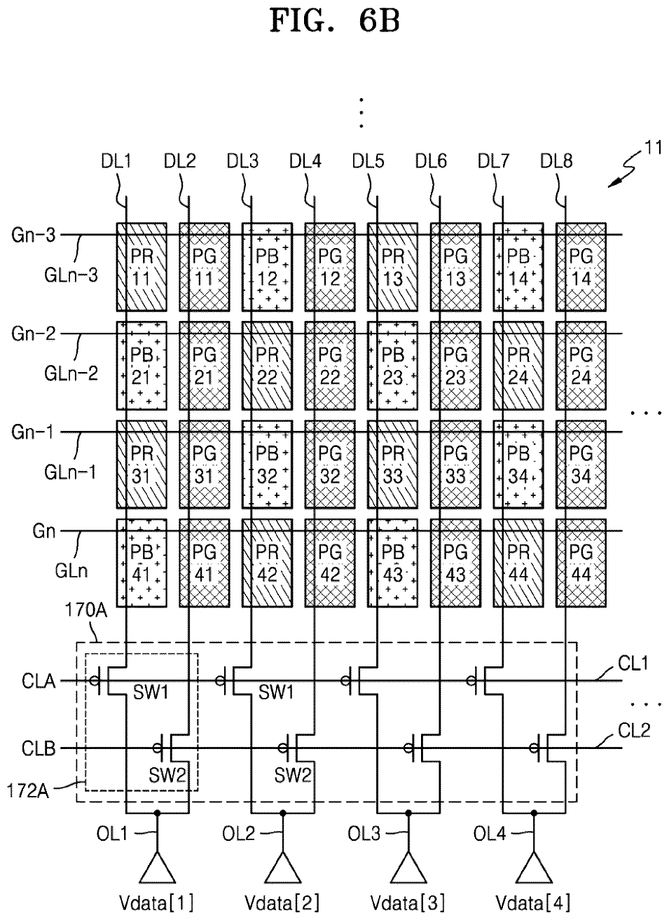

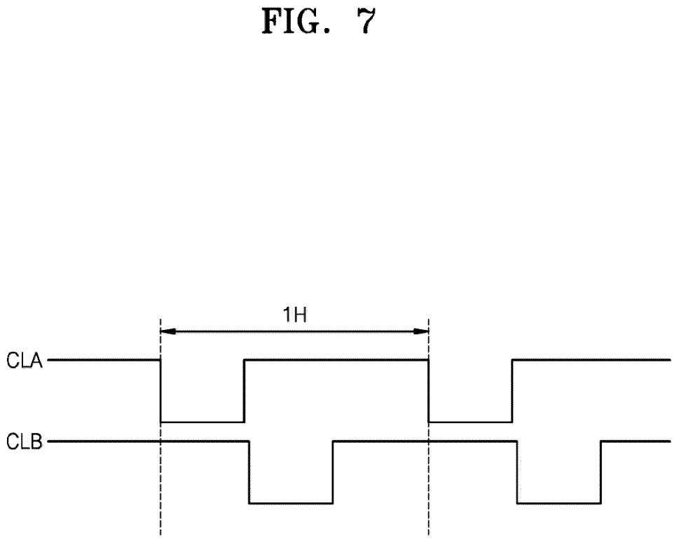

FIGS. 6A and 6B are diagrams for describing a demultiplexer, according to an embodiment. FIG. 7 is a timing diagram illustrating a switching operation of the demultiplexer of FIG. 6. The demultiplexer of FIG. 6B is an example to which the demultiplexer of FIG. 6A is applied. FIG. 6A is an embodiment of the demultiplexer DMX of FIG. 3.

FIG. 6A is an example of the demultiplexer DMX that selectively connects a k^{th} output line OLk to one pair of data lines adjacent to each other, that is, a 2k−1^{th} data line DL2k-1 to a 2k^{th} data line DL2k. The demultiplexer DMX may include a first switch SW1 and a second switch SW2.

The first switch SW1 may be disposed between the k^{th} output line OLk and the 2k−1^{th} data line DL2k-1. The first switch SW1 may connect the k^{th} output line OLk to the 2k−1^{th} data line DL2k-1 by a first control signal CLK, and may apply the data signal Vdata applied to the k^{th} output line OLk to the 2k−1^{th} data line DL2k-1.

The second switch SW2 may be disposed between the k^{th} output line OLk and the 2k^{th} data line DL2k. The second switch SW2 may connect the k^{th} output line OLk to the 2k^{th} data line DL2k by a second control signal CLB, and may apply the data signal Vdata applied to the k^{th} output line OLk to the 2k^{th} data line DL2k.

A distribution control signal CCS may include a first control signal CLA and a second control signal CLB. The first control signal CLA and the second control signal CLB may be alternately applied at different timings so as not overlap each other.

A plurality of pixels PX may include a first pixel PR, a second pixel PB, and a third pixel PG emitting light of different colors. In an embodiment, in a column M1 in which the 2k−1^{th} data line DL2k-1 is disposed, the first pixel PR and the second pixel PB may be alternately arranged and may be connected to the 2k−1^{th} data line DL2k-1. In a column M2 in which the 2k^{th} data line DL2k is disposed, the third pixel PG may be repeatedly arranged and may be connected to the 2k^{th} data line DL2k. One of the 2k−1^{th} data line DL2k-1 and the 2k^{th} data line DL2k may be an odd data line DLo and the other may be an even data line DLe. FIG. 6A is an example in which the 2k−1^{th} data line DL2-1 is an odd data line DLo and the 2k^{th} data line DL2k is an even data line DLe. One pair of data lines connected to the demultiplexer DMX may be one pair of data lines, that is, an odd data line and an even data line, which are spaced apart from each other by one column interval. The first pixel PR may be a red pixel that emits red light, the second pixel PB may be a blue pixel that emits blue light, and the third pixel PG may be a green pixel that emits green light.

FIG. 6A illustrates the pixels PX connected to an n−1^{th} gate line GLn−1 disposed in an n−1^{th} row and an nth gate line GLn disposed in an nth row. Each of the gate lines GLn−1 and GLn of FIG. 6A may be the first gate line GWL of FIG. 4. Each of gate signals Gn−1 and Gn of FIG. 6A may be the gate signal GW of FIG. 4.

Referring to FIG. 6B, a data distributor 170A may include a plurality of demultiplexers 172A, and the pixel unit 11 may include a plurality of pixels PX. The data distributor 170A may be an embodiment of the data distributor 170 of FIG. 3.

In the pixel unit 11, a column in which the first pixel PR and the second pixel PB are alternately arranged and a column in which the third pixel PG is repeatedly arranged may be alternately repeated in a row direction. In the pixel unit 11, a plurality of gate lines and a plurality of data lines may be arranged. In an embodiment, each of the gate lines may be the first gate line GWL of FIG. 4. In FIG. 6B, for convenience of explanation, gate signals Gn−3 to Gn and gate lines GLn−3 to GLn of an n−3^{th} row to an nth row and data lines DL1 to DL8 of a first column to an eighth column are illustrated. The data lines may include odd data lines (e.g., DL1, DL3, DL5, DL7, . . . ) and even data lines (e.g., DL2, DL4, DL6, DL8, . . . ). One pair of data lines connected to the demultiplexer 172A may be one pair of data lines, that is, an odd data line and an even data line. Hereinafter, the demultiplexer 172A connected to a first output line OL1 will be described as an example, and the description may apply to the demultiplexers 172A connected to the remaining output lines.

The demultiplexer 172A may include a first switch SW1 and a second switch SW2.

The first switch SW1 may be disposed between the first output line OL1 and the first data line DL1. The first switch SW1 may be a transistor including a gate connected to a first control line CL1, a first terminal connected to the first output line OL1, and a second terminal connected to the first data line DL1. The first switch SW1 may be turned on by a first control signal CLA applied from the first control line CL1 to connect the first output line OL1 to the first data line DL1 and apply the data signal Vdata applied through the first output line OL1 to the first data line DL1.

The second switch SW2 may be disposed between the first output line OL1 and the second data line DL2. The second switch SW2 may be a transistor including a gate connected to a second control line CL2, a first terminal connected to the first output line OL1, and a second terminal connected to the second data line DL2. The second switch SW2 may be turned on by a second control signal CLB applied from the second control line CL2 to connect the first output line OL1 to the second data line DL2 and apply the data signal Vdata applied through the first output line OL1 to the second data line DL2.

The data signal Vdata may include a first data signal R applied to the first pixel PR, a second data signal B applied to the second pixel PB, and a third data signal G applied to the third pixel PG.

FIG. 7 is a diagram schematically illustrating control signals applied to control lines of a demultiplexer, according to an embodiment. Hereinafter, when an arbitrary signal is supplied, it may mean that an on-voltage of the signal is supplied.

Referring to FIG. 7, the first control signal CLA and the second control signal CLB may be supplied to the demultiplexer 172a from the controller 14 (see FIG. 2) through the first control line CL1 (see FIG. 6) and the second control line CL2 (see FIG. 6). The first control signal CLA and the second control signal CLB may be gate control signals that control turn-on and turn-off of the first switch SW1 and the second switch SW2 of the demultiplexer 172A. The first control signal CLA and the second control signal CLB may be square wave signals in which an on-voltage that turns on the first switch SW1 and the second switch SW2 and an off-voltage that turns off the first switch SW1 and the second switch SW2 are repeated. In an embodiment, an on-voltage of the first control signal CLA and the second control signal CLB may be a low-level voltage (first-level voltage), and an off-voltage may be a high-level voltage (second-level voltage).

The first control signal CLA and the second control signal CLB may be signals having the same waveform and having shifted phases. For example, the second control signal CLB may have the same waveform as the first control signal CLA and may be applied with a phase shift (phase delay) at certain intervals. In an embodiment, after the first control signal CLA is applied, the second control signal CLB may be applied. Timings at which voltage levels of the first control signal CLA and the second control signal CLB are inverted may be the same. A period during which an on-voltage of the first control signal CLA is maintained (hereinafter, referred to as an on voltage period) and a period during which an off-voltage is maintained (hereinafter, referred to as an off voltage period) may respectively overlap an off-voltage period and an on-voltage period of the second control signal CLB. Horizontal periods of the first control signal CLA and the second control signal CLB may be about 1H.

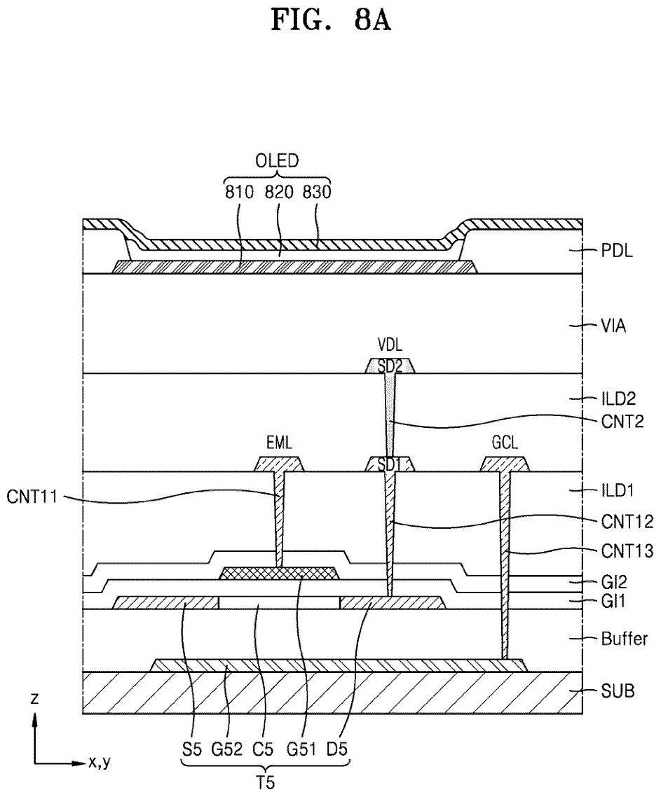

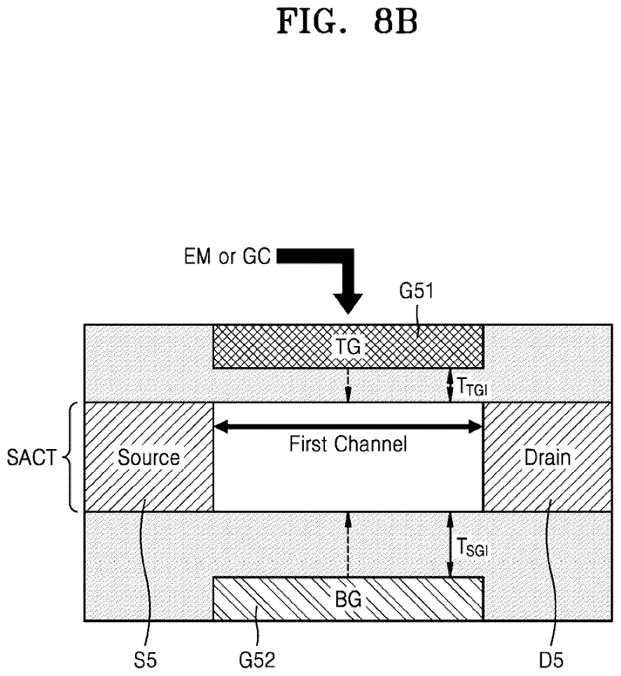

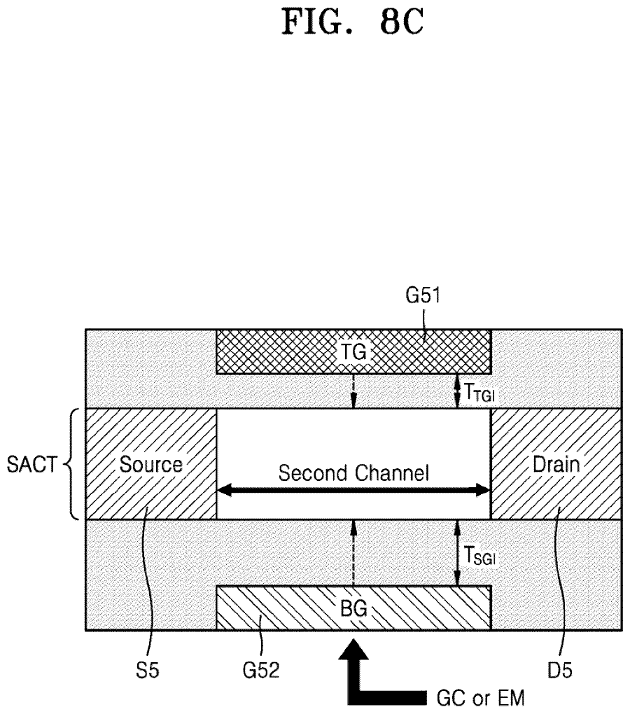

FIG. 8A is a diagram illustrating a part of a display apparatus, according to an embodiment. FIG. 8A illustrates a light-emitting device and a fifth transistor having a duale gate structure of FIG. 4A. FIGS. 8B and 8C are cross-sectional views for describing a structure and an operation of a fifth transistor, according to an embodiment.

Referring to FIG. 8A, a thin-film transistor T5 having a dual gate structure may be disposed on a substrate SUB.

The substrate SUB may include, for example, a glass material, a ceramic material, a metal material, or a flexible or bendable material. The substrate SUB may have a single-layer structure including an organic layer, or a multi-layer structure including an organic layer and an inorganic layer. For example, the substrate SUB may have a stacked structure including a first base layer, a barrier layer, and a second base layer. Each of the first base layer and the second base layer may be an organic layer including a polymer resin. Each of the first base layer and the second base layer may include a transparent polymer resin. The barrier layer may prevent penetration of an external foreign material and may have a single or multi-layer structure including an inorganic material such as, for example, silicon nitride (SiNₓ) or silicon oxide (SiOₓ).

A buffer layer Buffer may be disposed on the substrate SUB, and a second gate electrode G52 of the thin-film transistor T5 having a dual gate structure may be disposed between the substrate SUB and the buffer layer Buffer. The second gate electrode G52 may be disposed to correspond to at least a channel region C5 of the thin-film transistor T5. The buffer layer Buffer may be an inorganic insulating layer having a single or multi-layer structure including SiO2 or SiNx.

A semiconductor layer SACT may be disposed on the buffer layer Buffer, and the semiconductor layer SACT may include a silicon semiconductor (polysilicon or p-si). The semiconductor layer SACT may have any of various curved shapes. As shown in FIG. 8A, the semiconductor layer SACT may include the channel region C5 of the fifth transistor T5, and a source region S5 and a drain region D5 disposed on both sides of the channel region C5. When viewed in a z-axis direction, a region overlapping a gate electrode of a thin-film transistor may be the channel region. That is, a channel region C5, the source region S5, and the drain region D5 of the fifth transistor T5 may be portions of the semiconductor layer SACT. The source region and the drain region of the semiconductor layer SACT may correspond to a first terminal (or second terminal) and a second terminal (or first terminal) of the transistor. The source region or the drain region may be interpreted as a source electrode or a drain electrode of the transistor. For example, a source electrode and a drain electrode of the fifth transistor T5 may correspond to the source region S5 and the drain region D5 doped with impurities around the channel region C5.

A first insulating layer GI1 may be disposed on the buffer layer Buffer and may cover the semiconductor layer SACT, and a second insulating layer GI2 may be disposed on the first insulating layer GI1. A first gate electrode G51 of the fifth transistor T5 may be disposed in an island shape between the first insulating layer GI1 and the second insulating layer GI2. Each of the first insulating layer GI1 and the second insulating layer GI2 may include an inorganic material such as, for example, silicon nitride (SiNx) or silicon oxide (SiOx).

A third insulating layer ILD2 may be disposed on the second insulating layer GI2, and a fourth insulating layer ILD2 may be disposed on the third insulating layer ILD1. The third gate line GCL and the fourth gate line EML may be disposed on the third insulating layer ILD1 to extend in the x-direction. Also, connection electrodes SD1 may be disposed on the third insulating layer ILD1.

One end of the connection electrode SD1 may be electrically connected to the drain region D5 of the fifth transistor T5 through a contact hole CNT12 passing through the first insulating layer GI1, the second insulating layer GI2, and the third insulating layer ILD1. The other end of the connection electrode SD1 may be electrically connected to a connection electrode SD2 disposed on the fourth insulating layer ILD2 through a contact hole CNT2 passing through the fourth insulating layer ILD2.

A gate electrode of the fifth transistor T5 may include a second gate electrode G52 that is a part of the third gate line GCL and a first gate electrode G51 that is a part of the fourth gate line EML. The first gate electrode G51 may be an upper gate electrode, and the second gate electrode G52 may be a lower gate electrode. That is, the fifth transistor T5 may have a dual gate structure including control electrodes disposed over and under the first semiconductor layer SACT.

The first gate electrode G51 of the fifth transistor T5 may be electrically connected to the fourth gate line EML through a contact hole CNT11 formed in the second insulating layer GI2 and the third insulating layer ILD1, and the second gate electrode G52 may be electrically connected to the third gate line GCL through a contact hole CNT13 formed in the buffer layer Buffer, the first insulating layer GI1, the second insulating layer GI2, and the third insulating layer ILD1. The drain region D5 of the fifth transistor T5 may be electrically connected to the connection electrode SD1 through the contact hole CNT12 formed in the first insulating layer GI1, the second insulating layer GI2, and the third insulating layer ILD1.

In an embodiment, as shown in FIG. 8A, the third gate line GCL may be connected to the first gate electrode G51 that is an upper gate electrode, and the fourth gate line EML may be connected to the second gate electrode G52 that is a lower gate electrode.

The fourth insulating layer ILD2 may be disposed on the third insulating layer ILD1, and the driving voltage line VDL may be disposed on the fourth insulating layer ILD2 to extend in the x-direction. Also, the connection electrodes SD2 may be disposed on the fourth insulating layer ILD2. The driving voltage line VDL may be electrically connected to the connection electrode SD1 through the contact hole CNT2 formed in the fourth insulating layer ILD2. Because the connection electrode SD1 is electrically connected to the drain region D5 of the fifth transistor T5, the driving voltage line VDL may be electrically connected to the drain region D5 of the fifth transistor T5. In an embodiment, the driving voltage line VDL may be directly connected to the drain region D5 without the connection electrode SD1, through a contact hole formed in the fourth insulating layer ILD2, the third insulating layer ILD1, the second insulating layer GI2 and the first insulating layer GI1, which may improve a resolution of the display apparatus. That is, the drain region D5 of the fifth transistor T5 may be electrically connected to the driving voltage line VDL through the contact hole formed in the fourth insulating layer ILD2, the third insulating layer ILD1, the second insulating layer GI2 and the first insulating layer GI1 without the connection electrode SD1 formed on the third insulating layer ILD1.

A fifth insulating layer VIA may be disposed on the fourth insulating layer ILD2, and an organic light-emitting diode OLED may be disposed as a light-emitting device on the fifth insulating layer VIA. The organic light-emitting diode OLED may include a pixel electrode 810, an intermediate layer 820, and a counter electrode 830. The pixel electrode 810 may be disposed on the fifth insulating layer VIA. The intermediate layer 820 may be disposed on the pixel electrode 810, and the counter electrode 830 may be disposed on the intermediate layer 820.

The intermediate layer 820 of the organic light-emitting diode OLED may include a low molecular weight material or a high molecular weight material. When the intermediate layer 820 includes a low molecular weight material, the intermediate layer 820 may have a single or stacked structure in which a hole injection layer (HIL), a hole transport layer (HTL), an emission layer (EML), an electron transport layer (ETL), and an electron injection layer (EIL) are stacked, and may include any of various organic materials such as, for example, copper phthalocyanine (CuPc), N,N′-Di(napthalene-1-yl)-N,N′-diphenyl-benzidine (NPB), or tris-8-hydroxyquinoline aluminum (Alq3). These layers may be formed by using, for example, vacuum deposition.

When the intermediate layer 820 includes a high molecular weight material, the intermediate layer 820 may generally have a structure including an HTL and an EML. In this case, the HTL may include, for example, poly(3,4-ethylenedioxythiophene) (PEDOT), and the EML may include a polymer material such as, for example, a polyphenylene vinylene (PPV)-based material or a polyfluorene-based material. The intermediate layer 820 may be formed by using, for example, screen printing, inkjet printing, laser-induced thermal imaging (LITI), or the like.

The intermediate layer 820 is not necessarily limited thereto, and may have any of various structures. The intermediate layer 820 may include a layer that is integrally formed over a plurality of pixel electrodes 810, or may include a layer that is patterned to correspond to each of the plurality of pixel electrodes 810.

That is, the counter electrode 830 may be integrally formed in a plurality of organic light-emitting diodes and may correspond to the plurality of pixel electrodes 810.

Because the organic light-emitting diodes OLED may be easily damaged by external moisture or oxygen, a thin-film encapsulation layer or a sealing substrate may be disposed on the organic light-emitting diodes OLED, and may cover and protect the organic light-emitting diodes OLED. The thin-film encapsulation layer may cover the display area DA and may extend to the outside of the display area DA. The thin-film encapsulation layer may include an inorganic encapsulation layer including at least one inorganic material and an organic encapsulation layer including at least one organic material.

A pixel-defining layer PDL may be disposed on the fifth insulating layer VIA. The pixel-defining layer PDL defines a pixel by having an opening corresponding to each pixel, that is, an opening through which at least a central portion of the pixel electrode 810 is exposed. Also, the pixel-defining layer PDL increases a distance between an edge of the pixel electrode 810 and the counter electrode 830 over the pixel electrode 810, which may prevent an arc or the like from occurring at the edge of the pixel electrode 810. The pixel-defining layer PDL may be formed of an organic material such as, for example, polyimide or hexamethyldisiloxane (HMDSO).

Referring to FIG. 8B, the fourth gate signal EM or the third gate signal GC may be applied to the first gate electrode G51, which is an upper gate electrode. When a gate signal is applied to the first gate electrode G51 and a gate-source voltage is equal to or greater than a threshold voltage, a first channel may be formed between the drain region D5 and the source region S5.

Referring to FIG. 8C, the third gate signal GC or the fourth gate signal EM may be applied to the second gate electrode G52, which is a lower gate electrode. When a gate signal is applied to the second gate electrode G52 and a gate-source voltage is equal to or greater than a threshold voltage, a second channel may be formed between the drain region D5 and the source region S5.

A thickness T_{TGI} of an insulating layer between the first gate electrode G51 and the semiconductor layer SACT may be less than a thickness T_{SGI} of an insulating layer between the second gate electrode G52 and the semiconductor layer SACT. That is, a thickness of the first insulating layer GI1 where the first gate electrode G51 is disposed may be less than a thickness of the buffer layer Buffer where the second gate electrode G52 is disposed.

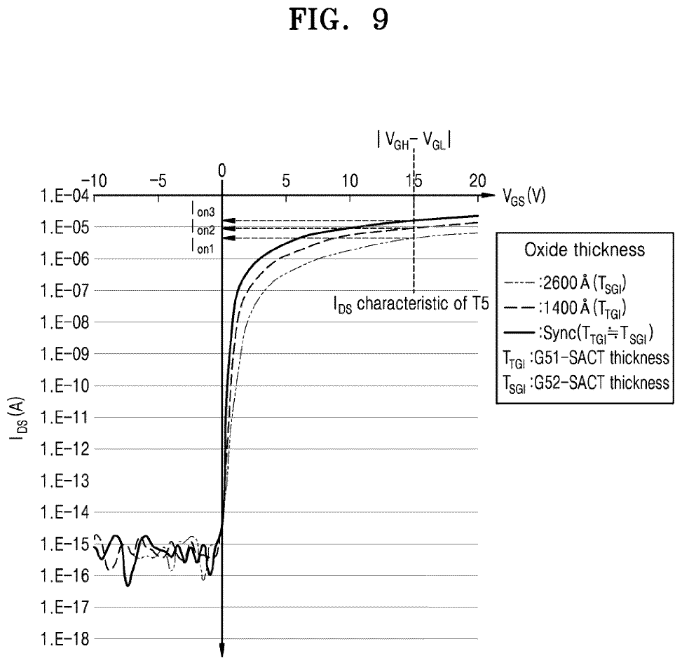

FIG. 9 is a diagram illustrating an experimental result for describing effects of embodiments of the present disclosure.

FIG. 9 is a graph illustrating a magnitude of current I_{DS} flowing through a channel according to a gate-source voltage V_{GS}, in the thin-film transistor T5 having a dual gate structure including the first gate electrode G51 and the second gate electrode G52, when a thickness T_{SGI} of an insulating film disposed between the second gate electrode G52 and the semiconductor layer SACT is about 2600 Å, when a thickness T_{TGI} of an insulating film between the first gate electrode G51 and the semiconductor layer SACT is about 1400 Å, and when the thickness T_{TGI} of the insulating film between the first gate electrode G51 and the semiconductor layer SACT and the thickness T_{SGI} of the insulating film between the second gate electrode G52 and the semiconductor layer SACT are about the same (sync).

Referring to FIG. 9, it is found that when the gate-source voltage V_{GS} is about 15 V, an intensity of current Iₒₙ₂ flowing through a first channel when a gate signal is applied to the first gate electrode G51 when the thickness T_{TGI} of the insulating film between the first gate electrode G51 and the semiconductor layer SACT is about 1400 Å is higher than an intensity of current Iₒₙ₁ flowing through a second channel when a gate signal is applied to the second gate electrode G52 when the thickness T_{SGI} of the insulating film between the second gate electrode G52 and the semiconductor layer SACT is about 2600 Å. That is, as a thickness of an insulating film between a gate electrode and the semiconductor layer SACT decreases, an intensity of current flowing through a channel formed in the semiconductor layer SACT may increase.

Also, referring to FIG. 9, it is found that when the gate-source voltage V_{GS} is about 15 V, an intensity of current Iₒₙ₃ flowing through the first channel and/or the second channel when a gate signal is applied to the first gate electrode G51 and/or the second gate electrode G52 when the thickness T_{TGI} of the insulating film between the first gate electrode G51 and the semiconductor layer SACT and the thickness T_{SGI} of the insulating film between the second gate electrode G52 and the semiconductor layer SACT are about the same (sync) is higher than an intensity of the current Iₒₙ₂ flowing through the first channel when a gate signal is applied to the first gate electrode G51 when the thickness T_{TGI} of the insulating film between the first gate electrode and the semiconductor layer SACT is about 1400 Å. That is, as the thickness T_{TGI} of the insulating film between the first gate electrode G51 and the semiconductor layer SACT and the thickness T_{SGI} of the insulating film between the second gate electrode G52 and the semiconductor layer SACT are almost the same (sync), an intensity of current flowing through a channel formed in the semiconductor layer SACT may increase.

Accordingly, according to an embodiment, even when the fifth transistor T5 has a dual gate structure, an intensity of current flowing through the semiconductor layer SACT may be controlled to increase by reducing a thickness of an insulating film between the second gate electrode G52 and the semiconductor layer SACT or by making a thickness of an insulating film between the second gate electrode G52 and the semiconductor layer SACT similar to a thickness of an insulating film between the first gate electrode G51 and the semiconductor layer SACT.

According to an embodiment, because the number of gate signals utilized to drive a pixel is reduced by sharing a gate signal of a thin-film transistor having a dual gate structure (for example, a fifth transistor T5) and another transistor, the number of gate driving circuits may be reduced, which may reduce manufacturing costs of a display apparatus.

Operations of a method or an algorithm described in relation to an embodiment may be directly implemented by hardware, a software module executed by hardware, or a combination thereof. The software module may reside in, for example, a random-access memory (RAM), a read-only memory (ROM), an erasable programmable ROM (EPROM), an electrically erasable programmable ROM (EEPROM), a flash memory, a hard disk, a removable disk, a CD-ROM, or any type of computer-readable recording medium.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

Embodiments of the present disclosure provide a display apparatus capable of reducing power consumption while reducing costs by reducing the area of a bezel area.

Effects of the disclosure are not limited to the above-mentioned effects, and other effects not mentioned herein will be clearly understood by one of ordinary skill in the art from the following description.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus, comprising:
a plurality of pixels, wherein each of the plurality of pixels comprises:
a light-emitting device;
a first transistor configured to control a current supplied to the light-emitting device;
a second transistor connected to a data line;
a third transistor connected between a second terminal of the first transistor and a gate of the first transistor;
a fourth transistor connected between a first terminal of the first transistor and a driving voltage line; and
a fifth transistor connected between the second terminal of the first transistor and the light-emitting device,
wherein a first gate of the fourth transistor and a gate of the fifth transistor are connected to a first gate line that supplies a first gate signal, and a gate of the third transistor and a second gate of the fourth transistor are connected to a second gate line that supplies a second gate signal.

2. The display apparatus of claim 1, wherein each of the plurality of pixels further comprises:
a first capacitor connected between the gate of the first transistor and the second transistor;
a second capacitor connected between the second transistor and the driving voltage line;
a sixth transistor connected between the gate of the first transistor and a first voltage line;
a seventh transistor connected between the light-emitting device and a second voltage line;
an eighth transistor connected between the second transistor and a third voltage line; and
a ninth transistor configured to supply a bias voltage to the first terminal of the first transistor.

3. The display apparatus of claim 2, further comprising:
a data driving circuit configured to supply a plurality of data signals to the plurality of pixels,
wherein the data driving circuit comprises a demultiplexer configured to alternately supply a data signal to a first data line based on a first control signal and supply the data signal to a second data line based on a second control signal.

4. The display apparatus of claim 3, wherein the demultiplexer comprises:
a first switch transistor connected to the first data line and a second switch transistor connected to the second data line,
wherein the first control signal is supplied to a gate of the first switch transistor, and then the second control signal is supplied to a gate of the second switch transistor.

5. The display apparatus of claim 3, wherein each of the plurality of pixels is any one of a first pixel that emits a red light, a second pixel that emits a green light, and a third pixel that emits a blue light,
wherein the first pixel and the third pixel are connected to the first data line, and the second pixel is connected to the second data line.

6. The display apparatus of claim 3, wherein the data driving circuit further comprises:
a data driver configured to output the plurality of data signals; and
a data distributor configured to alternately supply the plurality of data signals to the first data line and the second data line respectively based on the first control signal and the second control signal.

7. The display apparatus of claim 3, wherein
a gate of the eighth transistor is connected to the second gate line,
a gate of the second transistor is connected to a third gate line that supplies a third gate signal,
a gate of the sixth transistor is connected to a fourth gate line that supplies a fourth gate signal, and
a gate of the seventh transistor and a gate of the ninth transistor are connected to a fifth gate line that supplies a fifth gate signal.

8. The display apparatus of claim 7, further comprising:
a gate driving circuit configured to supply a plurality of gate signals to the plurality of pixels,
wherein each of the plurality of pixels operates in a non-emission period and an emission period during a frame period,
wherein the gate driving circuit is further configured to:
supply a first gate signal of a gate-off voltage to the first gate line in the non-emission period,
supply a fourth gate signal of a gate-on voltage to the fourth gate line, in a first interval during the non-emission period, and
supply a second gate signal of a gate-on voltage to the second gate line, in a second interval after the first interval during the non-emission period.

9. The display apparatus of claim 8, wherein the gate driving circuit is further configured to supply a third gate signal of a gate-on voltage to the third gate line, in a write interval after the second interval during the non-emission period.

10. The display apparatus of claim 9, wherein the gate driving circuit is further configured to supply a fifth gate signal of a gate-on voltage to the fifth gate line, in a third interval between the emission period and the write interval of the non-emission period.

11. The display apparatus of claim 10, wherein the gate driving circuit is further configured to supply a first gate signal of a gate-on voltage to the first gate line, in the emission period.

12. The display apparatus of claim 10, wherein a first on-time during which the gate driving circuit supplies a gate-on voltage in the first interval and the second interval is longer than a second on-time during which the gate driving circuit supplies a gate-on voltage in the write interval and the third interval.

13. A display apparatus, comprising:
a plurality of pixels, wherein each of the plurality of pixels comprises:
a light-emitting device;
a first transistor configured to control a current supplied to the light-emitting device;
a second transistor connected to a data line;
a third transistor connected between a second terminal of the first transistor and a gate of the first transistor;
a fourth transistor connected between a first terminal of the first transistor and a driving voltage line; and
a fifth transistor connected between the second terminal of the first transistor and the light-emitting device,
wherein a first gate signal is supplied to a gate of the third transistor and a first gate of the fourth transistor, and a second gate signal is supplied to a second gate of the fourth transistor and a gate of the fifth transistor.

14. The display apparatus of claim 13, wherein each of the plurality of pixels further comprises:
a first capacitor connected between the gate of the first transistor and the second transistor;
a second capacitor connected between the second transistor and the driving voltage line;
a sixth transistor connected between the gate of the first transistor and a first voltage line;
a seventh transistor connected between the light-emitting device and a second voltage line;
an eighth transistor connected between the second transistor and a third voltage line; and
a ninth transistor configured to supply a bias voltage to the first terminal of the first transistor.

15. The display apparatus of claim 14, wherein a data signal is alternately supplied to a first data line based on a first control signal and supplied to a second data line based on a second control signal.

16. The display apparatus of claim 15, wherein each of the plurality of pixels is any one of a first pixel that emits a red light, a second pixel that emits a green light, and a third pixel that emits a blue light,
wherein the first pixel and the third pixel are connected to the first data line, and the second pixel is connected to the second data line.

17. The display apparatus of claim 15, wherein
the first gate signal is supplied to a gate of the eighth transistor,
a third gate signal is supplied to a gate of the second transistor,
a fourth gate signal is supplied to a gate of the sixth transistor, and
a fifth gate signal is supplied to a gate of the seventh transistor and a gate of the ninth transistor.

18. The display apparatus of claim 17, wherein the pixel operates in a non-emission period and an emission period during a frame period,
wherein the non-emission period comprises:
a first interval during which the sixth transistor is turned on to apply a first voltage from the first voltage line to the gate of the first transistor; and
a second interval during which the third transistor and the fourth transistor are turned on to store a threshold voltage of the first transistor in the first capacitor, and the eighth transistor is turned on to apply a third voltage from the third voltage line to a node where the first capacitor is connected to the second capacitor.

19. The display apparatus of claim 18, wherein the non-emission period further comprises, after the second interval, a write interval during which the second transistor is turned on to apply a data signal from the data line to the gate of the first transistor.

20. The display apparatus of claim 19, wherein the non-emission period further comprises, after the write interval, a third interval during which the seventh transistor is turned on to supply a second voltage from the second voltage line to the light-emitting device, and the ninth transistor is turned on to supply the bias voltage to the first terminal of the first transistor.
